(19) United States
(12) Patent Application Publication
(10) Pub. No.: US 2015/0351267 A1
(43) Pub. Date: Dec. 3, 2015

(54) LATCHING ASSEMBLIES FOR ENCLOSURES

(71) Applicant: Emerson Network Power, Energy Systems, North America, Inc., Warrenville, IL (US)

(72) Inventors: Akshay Dinesh SHAH, Khamgaon (IN); Prasad Deeliprao VATNI, Latur (IN)

(21) Appl. No.: 14/728,184

(22) Filed: Jun. 2, 2015

(30) Foreign Application Priority Data
Jun. 2, 2014 (IN) 1820/MUM/2014

(51) Int. Cl. H05K 5/02

(52) U.S. Cl. CPC H05K 5/0226; H05K 5/0217; H05K 5/0221; H05K 5/0239

(57) ABSTRACT

An enclosure includes a base, a hood pivotably coupled to the base, and a latching assembly for coupling the hood to the base. The hood is configured to move between a closed position and an open position. The latching assembly includes a fixed bracket coupled to the base, a latch coupled to the hood and configured to move between an extended position and a retracted position, a spring element coupled to the latch and configured to bias the latch in the extended position to releasably couple the latch to the fixed bracket when the hood is in the open position, and a fastener coupled to the latch. The fastener is configured to move the latch to the retracted position to disengage the latch from the fixed bracket allowing the hood to move to the closed position. Other example enclosures and latching assemblies are also disclosed.

### CROSS-REFERENCE TO RELATED APPLICATION

This application claims the benefit of Indian Application No. 1820/MUM/2014 filed Jun. 2, 2014. The entire disclosure of the above application is incorporated herein by reference.

### FIELD

The present disclosure relates to latching assemblies for enclosures.

### BACKGROUND

This section provides background information related to the present disclosure which is not necessarily prior art.

Enclosures for housing telecommunications equipment such as power transfer switches, meters, etc. typically include a base and a movable hood for accessing an interior portion of the enclosures. For example, the hood may substantially cover a meter coupled to a power transfer switch, provide protection against tampering of the meter and/or power transfer switch, etc.

### SUMMARY

This section provides a general summary of the disclosure, and is not a comprehensive disclosure of its full scope or all of its features.

According to one aspect of the present disclosure, an enclosure for housing telecommunications equipment includes a base, a hood pivotably coupled to the base, and a latching assembly for coupling the hood to the base. The hood is configured to move between a closed position and an open position. The latching assembly includes a fixed bracket coupled to the base, a latch coupled to the hood and configured to move between an extended position and a retracted position, a spring element coupled to the latch and configured to bias the latch in the extended position to releasably couple the latch to the fixed bracket when the hood is in the open position, and a fastener coupled to the latch. The fastener is configured to move the latch to the retracted position to disengage the latch from the fixed bracket allowing the hood to move to the closed position.

According to another aspect of the present disclosure, an enclosure for housing telecommunications equipment includes a base, a hood pivotably coupled to the base, and a latching assembly for coupling the hood to the base. The hood is configured to move between a closed position and an open position. The latching assembly includes a fixed bracket having a base portion coupled to the base and a projection extending from the base portion, and a movable bracket coupled to the hood and configured to move between an extended position and a retracted position. The movable bracket defines a slot for receiving the projection of the fixed bracket when the movable bracket is moved to the extended position.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an isometric view of an enclosure including a base, a hood, and a latching assembly coupling the base and the hood according to one example embodiment of the present disclosure.

FIG. 2 is an isometric view of the enclosure of FIG. 1 with the hood in its open position and an enlarged view of the latching assembly including a latch in its retracted position.

FIG. 3 is an isometric view of the latch of FIG. 2.

FIG. 4 is an isometric view of a fixed bracket of the latching assembly FIG. 1.

FIG. 5A is a side view of the enclosure of FIG. 1 with the hood in its open position, and the latch in its extended position and coupled to the fixed bracket.

FIG. 5B is a side view of the enclosure of FIG. 1 with the hood in its open position and the latch in its extended position.

FIG. 5C is a side view of the enclosure of FIG. 1 with the hood in its open position and the latch in its retracted position.

FIG. 6 is a perspective view of the enclosure of FIG. 1 with the latch in its extended position.

FIG. 7 is an isometric view of an enclosure including a base, a hood, and a latching assembly coupling the base and the hood according to another example embodiment

FIG. 8 is a perspective view of the latching assembly of FIG. 7 including a fixed bracket, a latch, a spring element, and a fastener.

FIG. 9 is a perspective view of the fixed bracket of FIG. 8.

FIG. 10 is an isometric view of an enclosure including a base, a hood, and a latching assembly having a fixed bracket and a movable bracket according to yet another example embodiment.

FIG. 11 is a side view of the enclosure of FIG. 10 with the hood in its open position and the movable bracket in its retracted position.

FIG. 12 an isometric view of the movable bracket of FIGS. 10 and 11.

Corresponding reference numerals indicate corresponding parts or features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

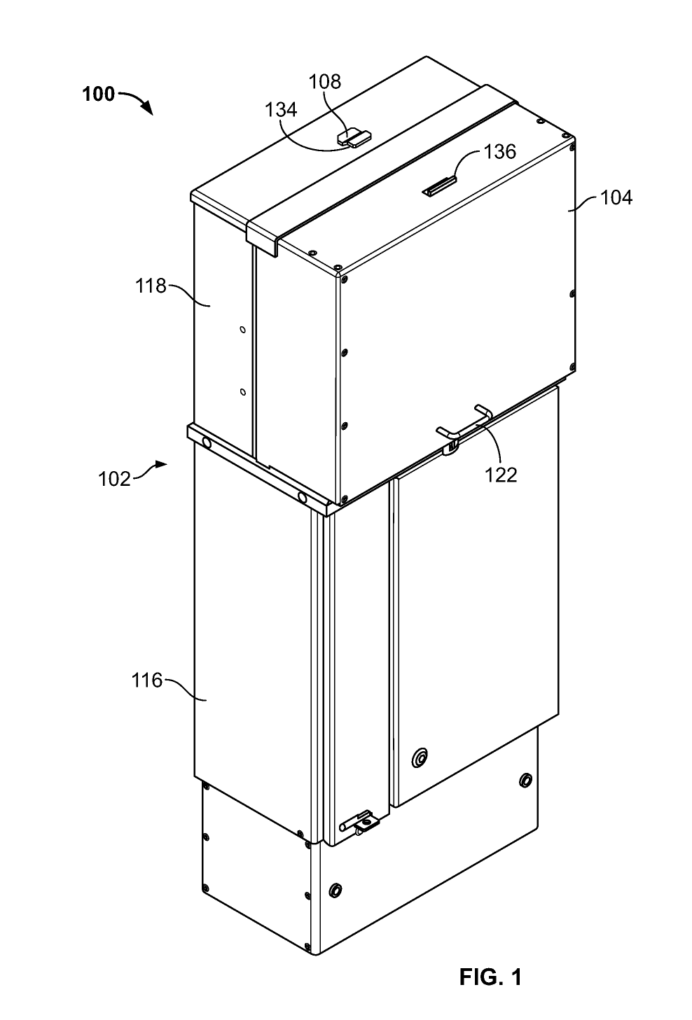

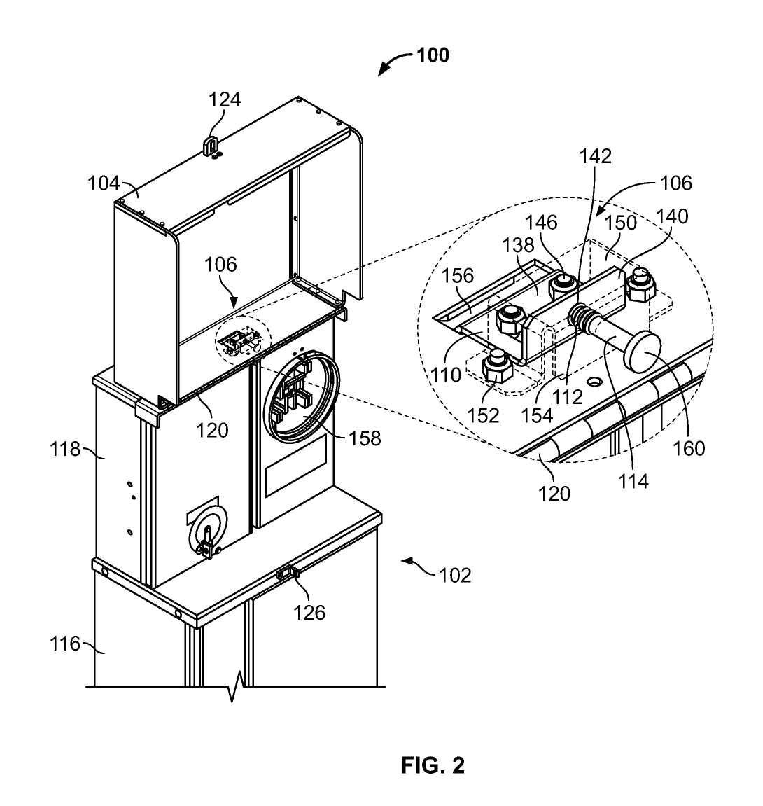

An enclosure for housing telecommunications equipment according to one example embodiment of the present disclosure is illustrated in FIGS. 1 and 2, and indicated generally by reference number 100. As shown in FIGS. 1 and 2, the enclosure 100 includes a base 102, a hood 104 pivotably coupled to the base 102, and a latching assembly 106 for coupling the hood 104 to the base 102. The hood 104 is configured to move between a closed position and an open position. The latching assembly 106 includes a fixed bracket 108 coupled to the base 102 (see FIG. 1), a latch 110 coupled to the hood 104 (see FIG. 2) and configured to move between an extended position and a retracted position, a spring element 112 coupled to the latch 110 and configured to bias the latch 110 in the extended position to releasably couple the latch 110 to the fixed bracket 108 when the hood 104 is in the open position, and a fastener 114 coupled to the latch 110 and configured to move the latch 110 to the retracted position to disengage the latch 110 from the fixed bracket 108 allowing the hood 104 to move to the closed position.

As shown in FIGS. 1 and 4, the fixed bracket 108 includes a base portion 128 coupled to an upper base portion 118 of the base 102, a projection 132, and an angled portion 130 coupling the projection 132 to the base portion 128. As shown in FIG. 4, the projection 132 and the base portion 128 may be substantially parallel to each other and extend in different planes.

When the fixed bracket 108 is coupled to the base 102, the angled portion 130 extends from the base portion 128 so that the projection 132 is offset from an outside surface of the base 102. As such, the base 102 and the fixed bracket 108 define an opening 134 (e.g., sometimes referred to as a lug receiving space) for receiving a projection 136 (e.g., sometimes referred to as a lug) of the latch 110 when the fixed bracket 108 is coupled to the base 102. As further explained below, when the hood 104 is moved to its fully open position, the lug 136 of the latch 110 may be positioned in the lug receiving space 134 and engage the projection 132 of the fixed bracket 108 to releasably couple the latch 110 to the fixed bracket 108. As such, the hood 104 may be secured to the base 102 to prevent the hood 104 from falling back to a closed position (e.g., as shown in FIG. 1) due to a gust of wind, etc., without a user first decoupling the latch 110 from the fixed bracket 108.

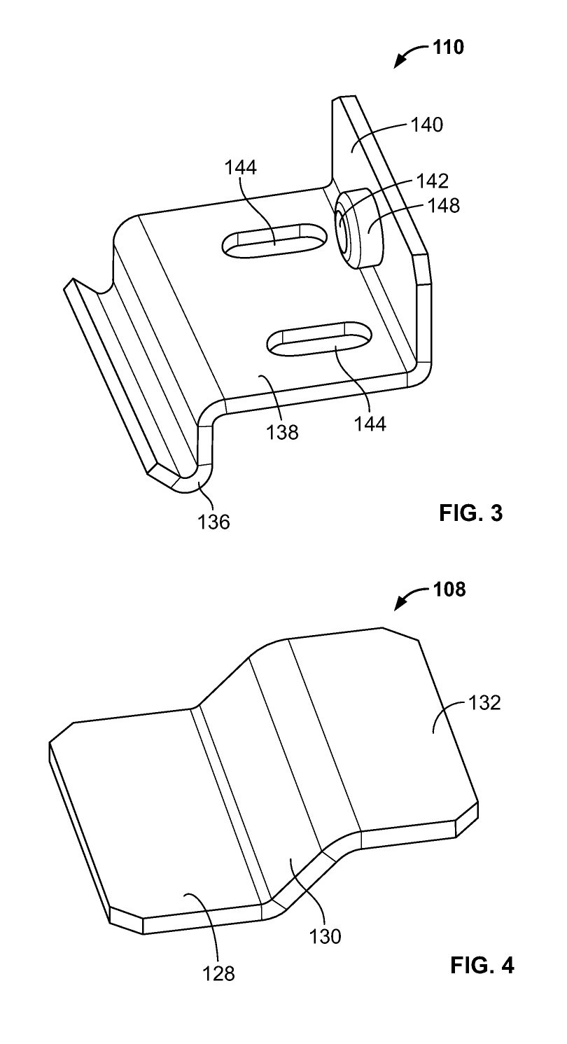

As shown in FIGS. 1-3, the latch 110 (e.g., sometimes referred to as a movable bracket) includes a base portion 138, the lug 136 extending from one end of the base portion 138, and an angled portion 140 extending from the other end of the base portion 128. Preferably, the angled portion 140 extends in a plane substantially perpendicular to a plane of the base portion 138 and the lug 136 extends into an opening 156 of the hood 104 such that the lug 136 is at least partially positioned adjacent an outside surface of the hood 104. Additionally, the lug 136 of FIG. 3 includes slanted flange portions to form a “U” like shape for engaging the projection 132 of the fixed bracket 108.

In other embodiments, the angled portion 140 and/or the lug 136 may be positioned in another suitable arrangement and/or have another suitable shape if desired.

As shown in FIG. 3, the lug 136 and the angled portion 140 extend along the entire edge surface of the opposing ends of the base portion 128. In other embodiments, the lug 136 and/or the angled portion 140 may extend a distance more or less than the edge surfaces, extend at different angles, etc. without departing from the scope of the disclosure.

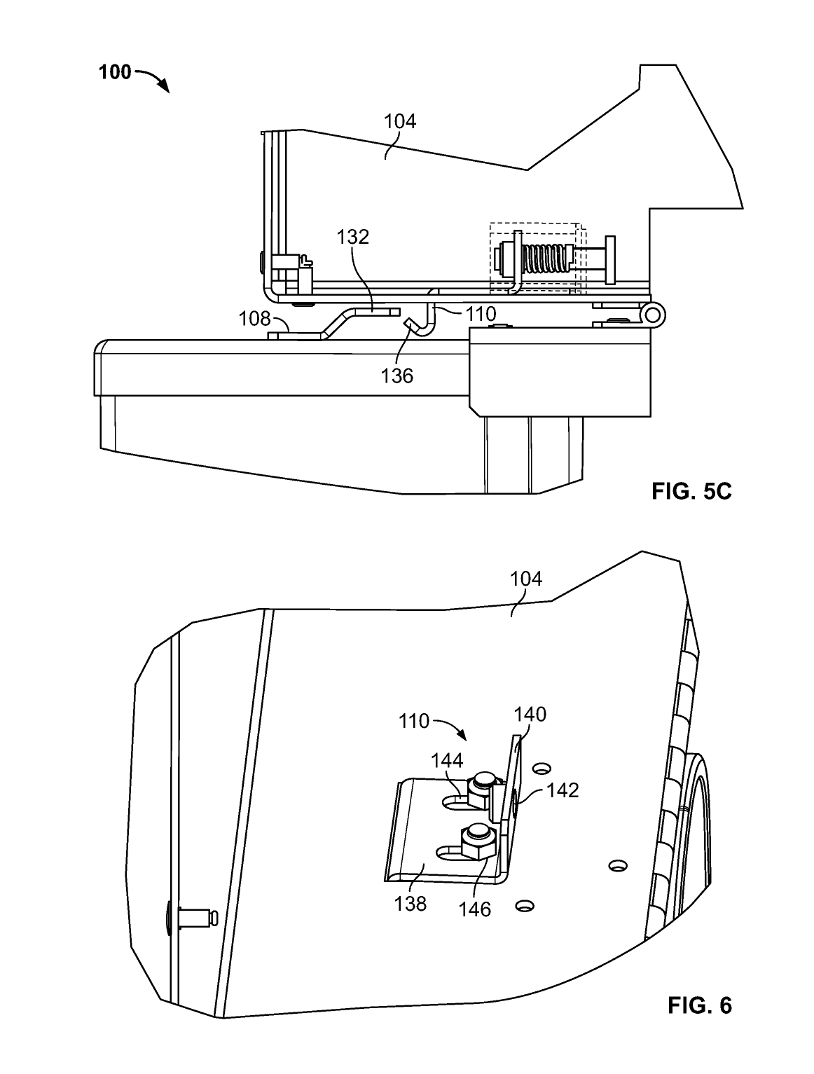

The latch 110 may include one or more openings. For example, the latch 110 of FIGS. 2-3 and 6 may include an opening 142 for receiving the fastener 114 (as further explained below) and two slots 144 having an elongated shape. Fasteners 146 of the latching assembly 106 may be inserted through the slots 144 for coupling the latch 110 to the hood 104. The fasteners 146 may include any other suitable fasteners such as bolts, screws, rivets, nuts, etc. Preferably, the fasteners 146 include bolts and nuts (as shown in FIG. 2) to hold the latch 110 in contact with the hood 104, while still allowing the latch 110 to move. As such, when the latch 110 is coupled to the hood 104, the slots 144 permit guided linear movement of the latch 110 when the latch 110 is moved between the extended position and the retracted position as explained herein.

As shown in FIG. 2, the fastener 114 of the latching assembly 106 is coupled to the latch 110 by inserting an end of the fastener 114 through the opening 142. For example, the fastener 114 may include a threaded portion that is at least partially passed through the opening 142, and into a nut 148. As shown in FIG. 3, the nut 148 may be attached to the angled portion 140 of the latch 110. Alternatively, the nut 148 may be separated from the latch 110. In other embodiments, the opening 142 may include threads corresponding to threads of the fastener 114. In such examples, the nut 148 may be omitted if desired. In other embodiments, the fastener 114 may be welded to the latch 110.

In some embodiments, the fastener 114 may include a head 160 for moving the latch 110 between the extended and retracted positions as further explained below. For example, the head 160 (e.g., sometimes referred to as a gripping portion) may allow a user to easily grip and move the fastener 114.

The fastener 114 may be any suitable fastener including for example, a bolt, a screw, etc. Preferably, the fastener 114 includes a bolt (e.g., a threaded bolt, etc.). In such cases, the fastener 114 and the spring element 112 positioned about the fastener 114 (as further explained below) may be considered a spring loaded bolt assembly.

As shown in FIG. 2, the spring element 112 is coupled to the angled portion 140 of the latch 110. For example, the spring element 112 may be positioned about the fastener 114 between the angled portion 140 and the head 160 of the fastener 114. Thus, when the spring element 112 is in its static state (e.g., no external forces acting on the spring element), the spring element 112 may bias the latch 110 into its extended position. In some embodiments, the spring element 112 may be compressed by the latch 110 when the latch 110 is moved to its retracted position (e.g., by pulling the head 160 of the fastener 114, etc.).

In the example embodiment of FIG. 2, the latching assembly 106 may include a cover 150 (shown in phantom lines) having one or more openings for receiving the fastener 114. As shown in FIG. 2, the opening 142 of the latch 110 may be coaxially aligned with the openings of the cover 150. As such, the fastener 114 may be inserted through both openings when the latching assembly 106 is assembled.

Additionally, the cover 150 may be coupled to the hood 104. For example, the cover 150 may be coupled to the hood 104 with fasteners 152 (e.g., bolts, screws, nuts, rivets, etc.). As such, the cover 150 may be rigidly attached and therefore not movable relative to the hood 104 when, for example, the latch 110 is moved. In such examples, the cover 150 may include a wall 154 that acts as a barrier allowing the spring element 112 to compress against its surface without moving. Thus, when the latch 110 is moved to its retracted position, the spring element 112 may compress against the cover 150. Alternatively, another suitable structure may be employed in addition to or in place of the cover 150 such as a bracket (e.g., an “L” shaped bracket, etc.), a different wall, etc.

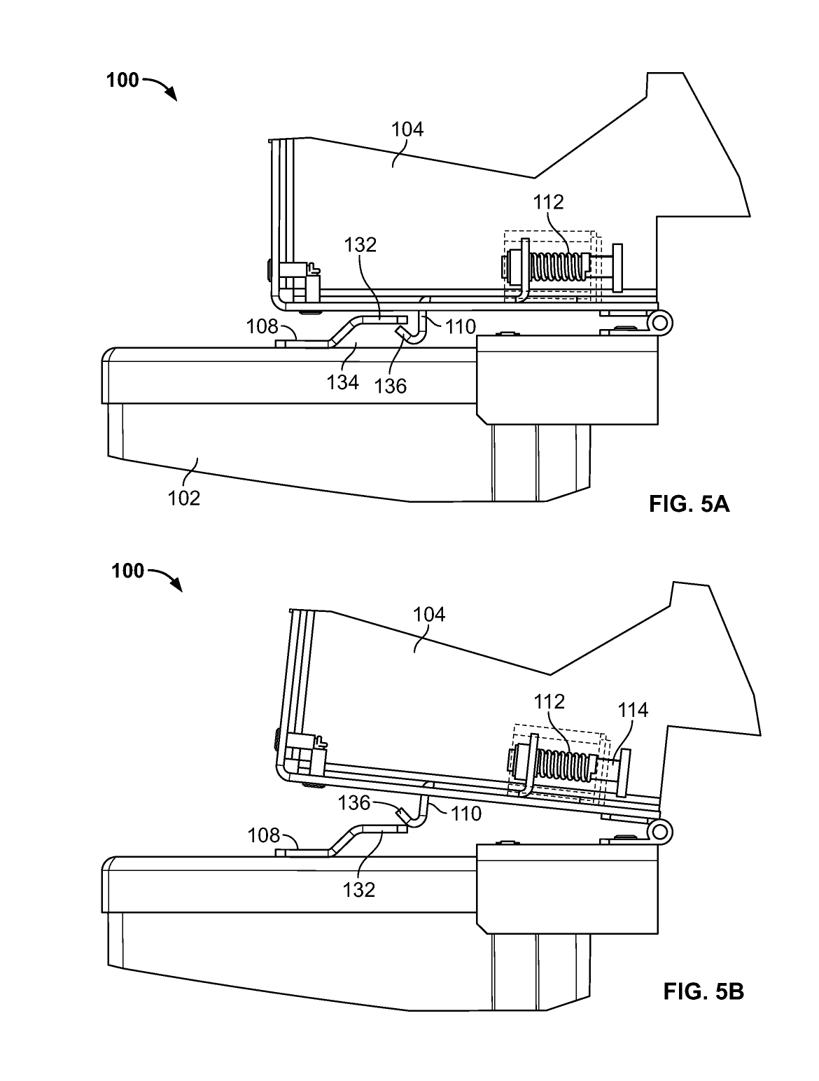

For example, FIGS. 5A-C illustrate the enclosure 100 of FIGS. 1 and 2 with the latch 110 in various positions relative to the fixed bracket 108 when the hood 104 is in its open position. FIG. 5A illustrates the latch 110 in its extended position (e.g., a static state). In particular, the spring element 112 biases the lug 136 of the latch 110 into the opening 134 defined by the projection 132 of the fixed bracket 108 and the base 102. Thus, in the example of FIG. 5A, the lug 136 is positioned between the base 102 and the fixed bracket 108.

FIG. 5B also illustrates the latch 110 in its extended position as explained above. The lug 136 of FIG. 5B, however, is positioned above the projection 132 of the fixed bracket 108. In such cases, the hood 104 may be forced downwardly to move the latch 110 and therefore the fastener 114 coupled to the latch 110. Alternatively and/or additionally, a user may move (e.g. pull) the fastener 114 to move the latch 110 as explained above. Once the latch 110 (e.g., in particular the lug 136) clears the projection 132, the spring element 112 may bias the latch 110 back to its extended position as explained above.

FIG. 5C illustrates the latch 110 in its retracted position (e.g., a compressed state). In particular, the latch 110 is moved so that the lug 136 can clear the projection 132 (as explained above) and thus, disengage the fixed bracket 108. After which, the hood 104 may be moved from its fully open position to its closed position, a position between its fully open position and its fully closed position, etc.

Referring back to FIG. 1, the hood 104 may include a handle 122 adjacent a lower portion of the hood 104. The handle 122 allows a user to move the hood 104 between the closed position (as shown in FIG. 1) and the open position (as shown in FIG. 2). When the hood 104 is in the closed position, the hood 104 may be secured to the base 102 via a locking device. For example, the base 102 may include a protrusion 126 and the hood 104 may include a receiver 124 for receiving the protrusion 126. When the hood 104 is moved to the closed position, the protrusion 126 enters the receiver 124, and a security device (e.g., a lock such as a pad lock, etc.) may be placed in an opening of the protrusion 126 to secure the hood 104 to the base 102.

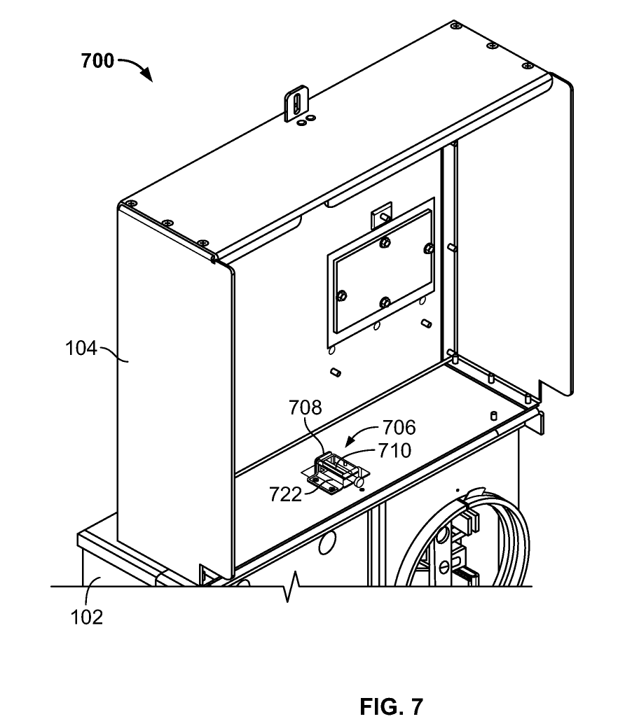

Although FIGS. 1-6 illustrate a particular configuration of a latching assembly, it should be clear other example latching assemblies including different latches, fixed brackets, etc. may be employed without departing from the scope of the disclosure. For example, FIG. 7 illustrates another enclosure 700 including the base 102 and the hood 104 of FIG. 1, and a latching assembly 706 for coupling the hood 104 to the base 102. The latching assembly 706 includes a fixed bracket 708 coupled to the base 102 (and extending through the hood 104 when the hood 104 is moved to its open position as explained below), and a latch 710 coupled to the hood 104.

As shown in FIG. 9, the fixed bracket 708 includes a base portion 716 for coupling to the outside surface of the base 102 and an angled portion 718 extending from the base portion 716. For example, and as shown in FIG. 9, the angled portion 718 preferably extends substantially perpendicular to the base portion 716.

The angled portion 718 may include an opening 720 for receiving the latch 710. For example, one end 726 of the latch may be inserted into the opening 720 such that the latch 710 is releasably coupled to the fixed bracket 708. In the example embodiments of FIGS. 7-10, the opening 720 may be substantially circular and the latch 710 may include a substantially cylindrical latch corresponding to the opening 720. Alternatively, another suitably shaped latch and/or opening may be employed including, for example, a substantially rectangular shape, a substantially triangular shape (e.g., with respect to a cross section of the latch), etc.

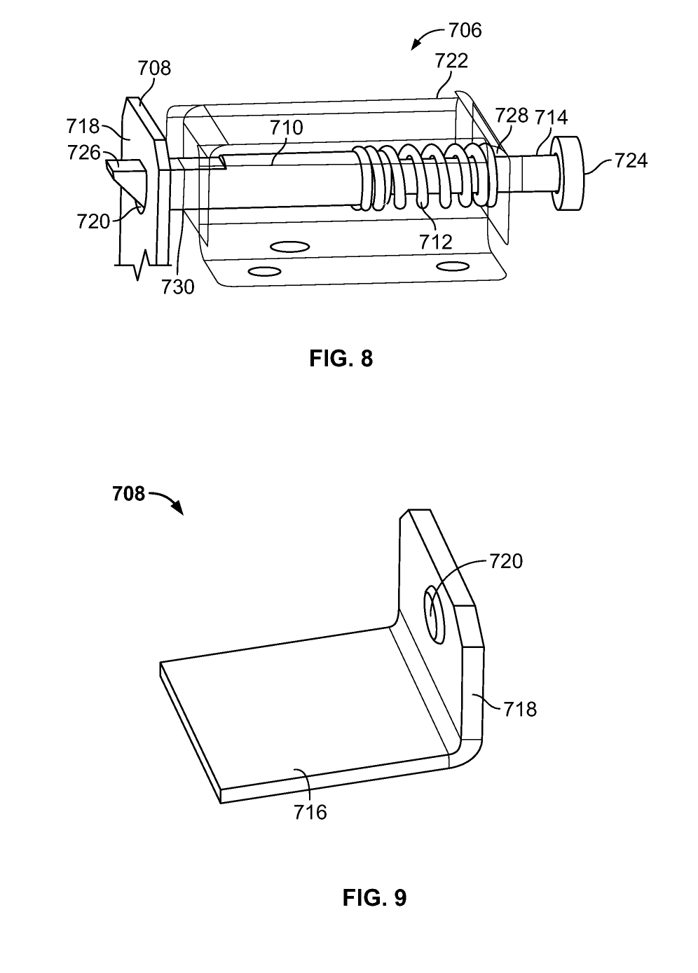

Similar to the latching assembly 106 of FIG. 2, the latching assembly 706 may include a fastener 714 coupled to the latch 710. The fastener 714 of FIG. 8 may be substantially similar to the fastener 114 of FIG. 2. For example, the fastener 714 may be inserted into an opening in the latch 710, may include a head 724 for gripping the fastener, etc. as explained above with respect to FIGS. 2 and 5A-C.

Similar to the latch 110 of FIG. 2, the latch 710 may be moved between an extended position and a retracted position. For example, and as shown in FIG. 8, a spring element 712 may be coupled to the latch 710 and configured to bias the latch 710 in its extended position (e.g., a static state) to releasably couple the latch 710 to the fixed bracket 708. In particular, the spring element 712 may be positioned about the fastener 714 between one side of the latch 710 and the head 724.

To disengage the latch 710 from the fixed bracket 708, a user may pull the fastener 714 (e.g., the head 724 of the fastener, etc.) to move the latch 710 into its retracted position. Once the latch 710 clears the opening 720 of the fixed bracket 708, the hood 104 may be moved from its fully open position.

Additionally, as shown in FIG. 8, the end 726 of the latch 710 may have a sloped portion. As such, as the hood 104 is moved to its open position, the sloped end 726 of the latch 710 will contact a top edge of the fixed bracket 708. When a downward force is applied to the hood 104, the latch 710 may be forced into its retracted position and therefore compress the spring element 712 until the latch 710 aligns with the opening 720 of the fixed bracket 708. Once aligned, the spring element 712 may bias the latch 710 to its extended position as explained above. Alternatively and/or additionally, a user may pull the fastener 714 to move the latch 710 into its retracted position as explained above.

Further, the latching assembly 706 may include a cover 722 substantially similar to the cover 150 of FIG. 2. For example, the cover 722 (shown in phantom lines) may be coupled to the hood 104, include a wall that allows the spring element 712 to compress against its surface without moving the cover 722, etc. as explained above with respect to FIGS. 2 and 5A-C.

Additionally, and as shown in FIG. 8, the cover 722 may define two openings 728, 730 on opposing ends of the cover for receiving the fastener 714. The openings 728, 730 may be coaxially aligned with the opening 720 of the fixed bracket 708. Thus, the fastener 714 can be inserted into the opening 728 of the cover 722 and the latch 710 (which is coupled to the fastener 714) can be inserted into the opening 730 of the cover 722 and the opening 720 of the fixed bracket 708. As such, the latch 710 may be releasably coupled the fixed bracket 708 as explained above.

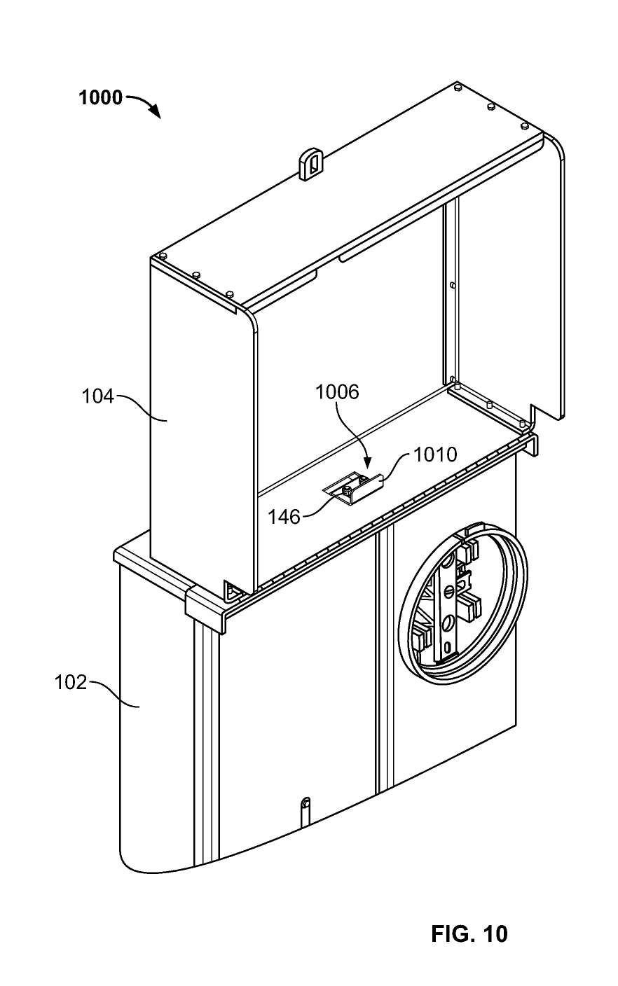

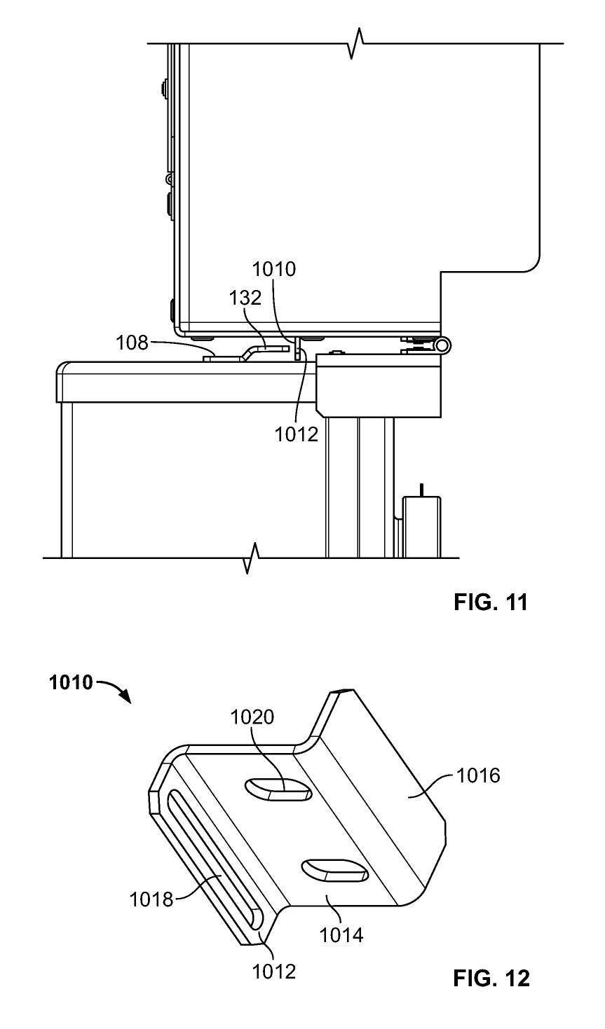

FIGS. 10 and 11 illustrate another example enclosure 1000 for housing telecommunications equipment. The enclosure 1000 includes the base 102 and the hood 104 of FIG. 1, and a latching assembly 1006 for coupling the hood 104 to the base 102. The latching assembly 1006 includes the fixed bracket 108 of FIG. 1 coupled to the base 102, and a movable bracket 1010 coupled to the hood 104 (e.g., an inside surface of the hood) and configured to move between an extended position and a retracted position.

As shown in FIGS. 11 and 12, the movable bracket 1010 includes two projections 1012, 1016, and a base portion 1014 coupling the two projections 1012, 1016. Preferably, the projection 1012 extends from one side of the base portion 1014 and passes through an opening in the hood 104 such that the projection 1012 is at least partially positioned adjacent an outside surface of the hood 104. The projection 1016 may extend from another side (e.g., the opposing side) of the base portion. Thus, the movable bracket 1010 may form a substantially “Z” shape. Alternatively, the movable bracket 1010 may form any other suitable shape if desired.

The movable bracket 1010 may function substantially similar as the latch 110 of FIG. 2. For example, the movable bracket 1010 may define slots 1020 for receiving the fasteners 146 of FIG. 1. In particular, and as shown in FIG. 12, the base portion 1014 includes two slots 1020 having an elongated shape. As shown in FIG. 10, the fasteners 146 may be inserted through the slots 1020 for coupling the movable bracket 1010 to the hood 104. Therefore, the slots 1020 permit guided linear movement of the movable bracket 1010 when the movable bracket 1010 is moved between the extended position and the retracted position (e.g., shown in FIG. 11) as explained above. Alternatively, more or less slots may be employed for receiving fasteners or the like. For example, the base portion 1014 may define one slot, four slots, etc.

The movable bracket 1010 also defines a slot 1018 for receiving the projection 132 of the fixed bracket 108 when the movable bracket 1010 is moved to the extended position. As such, the movable bracket 1010 may be releasably coupled to the fixed bracket 108. In particular, the projection 1012 of the movable bracket 1010 defines the slot 1018 that substantially corresponds to the projection 132 of the fixed bracket 108. For example, the slot 1018 may have a substantially similar shape as the projection 132, a substantially similar area as the surface area of the edge of the projection 132, etc.

In the example of FIGS. 10-12, the slot 1018 is an elongated oval shape that substantially matches the edge surface of the projection 132. Alternatively, the slot 1018 and/or the edge surface of the projection 132 may be any other suitable shape, size, etc. including, for example, rectangular, etc.

The projection 1016 can be used for moving the movable bracket 1010 between the extended position and the retracted position. For example, a user can move the movable bracket 1010 into a desired position by pulling and pushing the projection 1016.

The fixed brackets disclosed herein may be coupled to an outside surface of a base and the latches, movable brackets, etc. disclosed herein may be coupled to an inside surface of a hood. For example, and as shown in FIGS. 1 and 2, the fixed bracket 108 is coupled to the outside surface the base 102 and the latch 110 is coupled to the inside surface of the hood 104. Likewise, and as shown in FIGS. 10 and 11, the fixed bracket 108 is coupled to the outside surface of the base 102 and the movable bracket 1010 is coupled to the inside surface of the hood 104.

Additionally, the bases may include a lower base portion (e.g., the lower base portion 116 of FIGS. 1 and 2) and an upper base portion (e.g., the upper base portion 118 of FIGS. 1 and 2) positioned above the lower base portion. In such examples, a hood may be pivotably coupled to the upper base portion of a base. For example, and as shown in FIG. 2, the hood 104 is pivotably coupled to the base 102 via a hinge 120. As such, the hood may pivot about the hinge such that a user may selectively cover and uncover a portion of the enclosure. Alternatively, another suitable fastener, bracket, etc. may be employed to pivotably couple the hood 104 to the base 102.

In some examples, the hoods may be pivotable about the bases to an angle of about 180 degrees when the latch, the movable bracket, etc. is releasably coupled to the fixed bracket. For example, the angle between the hood 104 and the upper base portion 118 of the base 102 of FIG. 2 is about 180 degrees when the hood is moved to its open position and the latch 110 is coupled to the fixed bracket 108. As such, users may access telecommunications equipment, etc. in the base with greater ease compared to other enclosures in which the hood does not open to such an angle.

The fixed brackets disclosed herein may be coupled to a base by any suitable technique. For example, a fixed bracket may be coupled to a base by welding, adhesives, fasteners, etc.

Further, the enclosures disclosed herein may be suitable for various applications including, for example, telecommunications, etc. In such examples, the enclosures may include telecommunications equipment positioned within the enclosure and substantially covered by a hood when the hood is in the closed position as explained above. For example, and as shown in FIG. 2, the enclosure 100 includes telecommunications equipment 158 that may be covered by the hood 104 when the hood is in its closed position (e.g., see FIG. 1). The telecommunications equipment may include, for example, switching devices (e.g., power transfer switches, etc.), rectifiers, converters, batteries, meters, etc.

The features disclosed herein may include any suitable material including, for example, metal, plastic, etc. For example, one or more of the brackets, the latches, the covers, etc. disclosed herein may be sheet-metal formed by stamping and/or any other suitable process. Additionally, the fasteners such as the nuts, etc. may include a nylon material.

By employing one or more features disclosed herein, the enclosures may include a hood that is maintained in its open position without requiring a user to hold the hood. Additionally, the hood may be secured to an base as explained herein to prevent the hood from falling back to its closed position due to a gust of wind and/or another disturbance striking the hood.

Additionally, the latching assemblies disclosed herein have a simple but effective and reliable design, and are convenient to use. As such, construction, installation, maintenance, etc. of the latching assemblies and/or enclosures may take less time and/or money. Further, the enclosures disclosed herein may be tamper resistant and fluid tight.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An enclosure for housing telecommunications equipment, the enclosure comprising:
a base for housing telecommunications equipment;
a hood pivotably coupled to the base, the hood configured to move between a closed position and an open position; and
a latching assembly for coupling the hood to the base, the latching assembly including a fixed bracket coupled to the base, a latch coupled to the hood and configured to move between an extended position and a retracted position, a spring element coupled to the latch and configured to bias the latch in the extended position to releasably couple the latch to the fixed bracket when the hood is in the open position, and a fastener coupled to the latch and configured to move the latch to the retracted position to disengage the latch from the fixed bracket allowing the hood to move to the closed position.

2. The enclosure of claim 1 wherein the fastener includes a head for moving the latch to the retracted position to disengage the latch from the fixed bracket.

3. The enclosure of claim 1 wherein the latch is configured to move from the extended position to the retracted position when the latch engages the fixed bracket.

4. The enclosure of claim 1 wherein the latch includes a projection for releasably coupling the latch to the fixed bracket when the hood is in the open position.

5. The enclosure of claim 4 wherein the base and the fixed bracket define an opening for receiving the projection of the latch.

6. The enclosure of claim 1 wherein the latch defines at least one slot and wherein the latching assembly includes at least one additional fastener configured for insertion through the at least one slot for coupling the latch to the hood.

7. The enclosure of claim 6 wherein the at least one slot permits guided linear movement of the latch when the latch is moved between the extended position and the retracted position.

8. The enclosure of claim 1 wherein the latching assembly includes a cover coupled to the hood.

9. The enclosure of claim 8 wherein the cover defines at least one opening, wherein the latch defines an opening coaxially aligned with the at least one opening of the cover, and wherein the fastener is configured for insertion into the at least one opening of the cover and into the opening of the latch.

10. The enclosure of claim 8 wherein the cover defines two openings, wherein the fixed bracket defines an opening coaxially aligned with the two openings of the cover, wherein the fastener is configured for insertion into one of the two openings of the cover, and wherein the latch is configured for insertion into the other opening of the two openings of the cover and the opening of the fixed bracket.

11. (canceled)

12. The enclosure of claim 1 wherein the base includes an inside surface and an outside surface opposing the inside surface and wherein the fixed bracket is coupled to the outside surface the base.

13. The enclosure of claim 12 wherein the hood includes an inside surface and an outside surface opposing the inside surface and wherein the latch is coupled to the inside surface the hood.

14. The enclosure of claim 1 wherein the hood is pivotable about the base to an angle of about 180 degrees when the latch is releasably coupled to the fixed bracket.

15. The enclosure of claim 1 wherein the latch is substantially cylindrical.

16. The enclosure of claim 1 wherein the fixed bracket defines an opening for receiving the latch.

17. An enclosure for housing telecommunications equipment, the enclosure comprising:
a base for housing telecommunications equipment;
a hood pivotably coupled to the base, the hood configured to move between a closed position and an open position; and
a latching assembly for coupling the hood to the base, the latching assembly including a fixed bracket having a base portion coupled to the base and a projection extending from the base portion, and a movable bracket coupled to the hood and configured to move between an extended position and a retracted position, the movable bracket defining a slot for receiving the projection of the fixed bracket when the movable bracket is moved to the extended position.

18. The enclosure of claim 17 wherein the slot of the movable bracket is a first slot, wherein the movable bracket defines a second slot, and wherein the latching assembly includes a fastener configured for insertion through the second slot for coupling the movable bracket to the hood.

19. The enclosure of claim 18 wherein the second slot permits guided linear movement of the movable bracket when the movable bracket is moved between the extended position and the retracted position.

20. The enclosure of claim 17 wherein the base includes an inside surface and an outside surface opposing the inside surface and wherein the fixed bracket is coupled to the outside surface the base.

21. (canceled)

22. The enclosure of claim 20 wherein the hood is pivotable about the base to an angle of about 180 degrees when the movable bracket is releasably coupled to the fixed bracket.

23. (canceled)
